(19) United States
(12) Patent Application Publication
(10) Pub. No.: US 2025/0056951 A1
(43) Pub. Date: Feb. 13, 2025

(54) DRIVER BACKPLANE, DISPLAY PANEL, SPLICING SCREEN AND ELECTRONIC APPARATUS

(71) Applicant: Chengdu Vistar Optoelectronics Co., Ltd., Chengdu (CN)

(72) Inventors: Chen SU, Chengdu (CN); Xiuqi HUANG, Chengdu (CN); Xuan CAO, Chengdu (CN)

(73) Assignee: Chengdu Vistar Optoelectronics Co., Ltd., Chengdu (CN)

(21) Appl. No.: 18/930,399

(22) Filed: Oct. 29, 2024

(30) Foreign Application Priority Data
Oct. 31, 2023 (CN) 202311425544.8

(51) Int. Cl. H01L 33/62; H01L 23/00

(52) U.S. Cl. CPC H01L 33/62; H01L 24/06; H01L 2224/06151; H01L 2224/06515; H01L 2924/1426

(57) ABSTRACT

A driver backplane, display panel, splicing screen and electronic apparatus. The driver backplane includes a drive function layer and a plurality of bonding electrode sets disposed on a side of the drive function layer. In one of the plurality of the bonding electrode columns closest to the first side and serving as a first bonding electrode column, the backup bonding electrodes of at least a part of the bonding electrode sets are disposed on a side of the primary bonding electrodes facing away from the first side.

### CROSS-REFERENCE TO RELATED APPLICATION

This application claims priority to Chinese Patent Application No. 202311425544.8, filed on Oct. 31, 2023, which is hereby incorporated by reference in its entirety.

### TECHNICAL FIELD

The present application relates to the technical field of display, and in particular to a driver backplane, display panel, splicing screen and electronic apparatus.

### BACKGROUND

With the development of display device manufacturing technology, mini light-emitting diode (Mini LED) and micro light-emitting diode (Micro-LED) are widely used due to their greater advantages in terms of superior brightness, resolution ratio, contrast ratio, energy consumption, service life, response speed and thermal stability. However, at present, Mini LED or Micro-LED display panels cannot be made into a monolithic screen with increased size due to the limitations of the mass transfer process, so it is necessary to splice multiple display panels with smaller size into a larger screen body. In order to realize seamless splicing, it is required for the splicing display panels to use side wirings to realize the connection between the front and back circuits. However, the side wirings occupy part of the space on the front side of the screen, and in the case of display panels with a relatively great pixel density (Pixels Per Inch, PPI), the side wirings have a low manufacturing tolerance rate, resulting in a low yield of the display panel.

### SUMMARY

Embodiments of the present application provide a driver backplane, display panel, splicing screen and electronic apparatus to overcome the above deficiencies in the related art.

In a first aspect, embodiments of the present application provide a driver backplane including a drive function layer, the drive function layer includes a bonding surface, a first side, and a second side. The first side and the second side are disposed on two sides of the bonding surface, respectively, and the first side is configured to attach to and splice with other display panels.

The driver backplane further includes a plurality of bonding electrode sets disposed on the bonding surface, each of the plurality of bonding electrode sets comprises a plurality of primary bonding electrodes and a plurality of backup bonding electrodes arranged in a first direction.

The plurality of bonding electrode sets are formed as a plurality of bonding electrode columns extending in a second direction and distributing in the first direction that intersects the second direction.

One of the plurality of the bonding electrode columns closest to the first side serves as a first bonding electrode column, and in the first bonding electrode column, the backup bonding electrodes of at least a part of the bonding electrode sets are disposed on a side of the primary bonding electrodes facing away from the first side; other bonding electrode columns other than the first bonding electrode column that serves as second bonding electrode columns, and in the second bonding electrode column, the backup bonding electrodes of the bonding electrode sets are disposed on the other side of the primary bonding electrodes adjacent to the first side.

In a second aspect, embodiments of the present application provide a display panel including the driver backplane provided by the embodiments of the present application, and a light emitting device electronically connected to the bonding surface of the driver backplane.

In a third aspect, embodiments of the present application provide a splicing display including at least two display panels provided by the embodiments of the present application, the first side of the driver backplane of at least one of the display panels is spliced with and attached to the first side or the second side of the driver backplane of the other at least one of the display panels.

In a fourth aspect, embodiments of the present application provide an electronic apparatus including the splicing display provided by the embodiments of the present application.

Compared with the related art, the present application has the following beneficial effects:

According to the driver backplane, the display panel, and the electronic apparatus provided in the embodiments in the present application, by adjusting the positions of the primary bonding electrodes and the backup bonding electrodes in the first bonding electrode column closest to the first side of the driving backplane, the distance from the bonding electrode in the first bonding electrode column closest to the first side of the driver backboard to the first side of the driver backplane can be increased, and a larger process space is reserved for side wirings. In this way, when a display panel with a larger pixel density is manufactured, there is a higher fault tolerance rate for the side wirings, thereby improving the yield of the display panels.

### BRIEF DESCRIPTION OF THE DRAWINGS

FIG. 1 is a first schematic view of a driver backplane in a related art.

FIG. 2 is a first schematic cross-section view of a driver backplane according to an embodiment of the present application.

FIG. 3 is a first schematic view of a bonding surface of a driver backplane according to an embodiment of the present application.

FIG. 4 is a second schematic view of a bonding surface of a driver backplane according to an embodiment of the present application.

FIG. 5 is a second schematic cross-section view of a driver backplane according to an embodiment of the present application.

FIG. 6 is a third schematic view of a bonding surface of a driver backplane according to an embodiment of the present application.

FIG. 7 is a fourth schematic view of a bonding surface of a driver backplane according to an embodiment of the present application.

FIG. 8 is a fifth schematic view of a bonding surface of a driver backplane according to an embodiment of the present application.

FIG. 9 is a second schematic view of a driver backplane in a related art.

FIG. 10 a sixth schematic view of a bonding surface of a driver backplane according to an embodiment of the present application.

### REFERENCE NUMERALS

100-drive function layer; 10-bonding surface; 11-first side; 12-second side; 211-primary bonding electrode; 212-backup bonding electrode; 210-bonding electrode group; 310-first side alignment; 320-second side alignment; 200-bonding electrode column; 201-first bonding electrode column; 202-second bonding electrode column; D1-first direction; D2-second direction.

### DETAILED DESCRIPTION

In order to make the purpose, technical solutions and advantages of the embodiments of the present application clearer, the technical solutions in the embodiments of the present application will be described clearly and completely in the following in conjunction with the accompanying drawings in the embodiments of the present application, and it is clear that the embodiments described are a part of the embodiments of the present application, and not all of the embodiments. The components of embodiments of the present application generally described and illustrated in the accompanying drawings herein may be arranged and designed in a variety of different configurations.

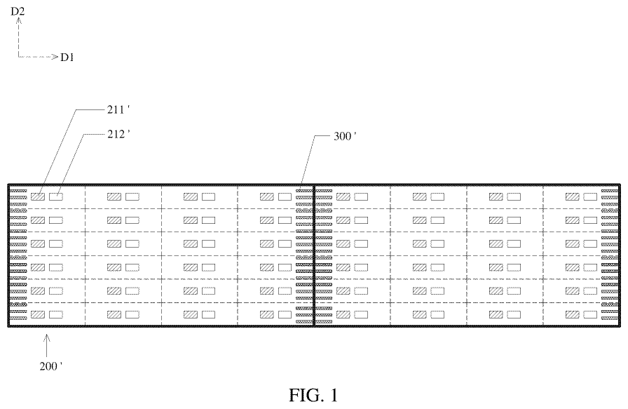

Referring to FIG. 1, in some individual display panels composing a splicing display, in order to ensure the illumination yields of the light emitting devices, a backup bonding electrode 212′ is usually provided for each of the primary bonding electrodes 211′ used to bind the light emitting devices, and a new light emitting device is set on the backup bonding electrode 212′ by a repair process to replace the faulty light emitting devices when the failure of the light emitting device bound on the primary bonding electrode 211′ is detected.

In order to achieve the seamless splicing of the display panels, the bezel of the display panel needs to be minimized as much as possible, and therefore the circuits on the front side of the display panel are usually required to be connected to the driver circuit on the back side of the display panel via the side wirings 300′.

However, the side wirings 300′ will occupy a certain space on the front side of the display panel, and if the space for the side wirings is too small, the side wirings process yield will be affected. Therefore it is difficult to further reduce the pixel density of the display panel.

In view of the above, the present embodiments provide a solution that can reserve a larger wiring space for the side wirings, and further increase the pixel density of a display panel. The solution provided in the present embodiments is described in detail below.

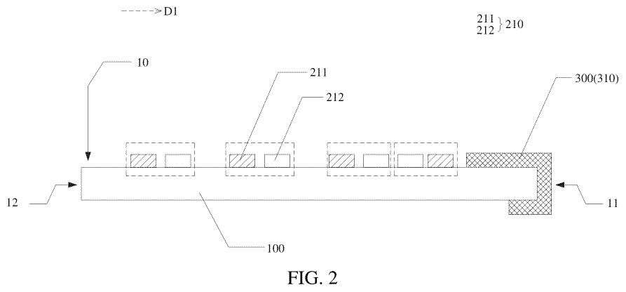

Referring to FIG. 2, FIG. 2 is a first schematic cross-section view of a driver backplane according to an embodiment of the present application. The driver backplane may include a drive function layer 100 and a plurality of bonding electrode sets 210 disposed on a side of the drive function layer 100.

The drive function layer 100 includes a bonding surface 10, a first side 11 and a second side 12 located on two sides of the bonding surface 10 in a first direction D1, respectively. In the present embodiments, the drive function layer 100 may include a plurality of film layer structures, such as a substrate, a buffer layer, an active layer, a plurality of metal layers, a plurality of insulating layers, and a flattened layer, or the like. The film layer structures of the drive function layer 100 may form a plurality of thin film transistors (TFTs) at different positions of the drive function layer 100, and the TFTs may cooperate with each other to form a plurality of drive units which are used to drive the light emitting devices to emit light.

Each bonding electrode set 210 (as shown by the dotted box in FIG. 2) may include a primary bonding electrode 211 and a backup bonding electrode 212 disposed in the first direction D1. The primary bonding electrode 211 and the backup bonding electrode 212 may be electrically connected to the driving units in the drive function layer 100. After the light emitting devices are bound to the primary bonding electrode 211 or the backup bonding electrode 212, the electrical energy provided by the driving units may be transmitted to the light emitting devices via the primary bonding electrodes 211 or the backup bonding electrodes 212.

The primary bonding electrode 211 is preferentially configured to bind to light emitting devices, and when the light emitting devices bound to the primary bonding electrode 211 fails, a new light emitting device is bound to the backup bonding electrode 212 corresponding to the primary bonding electrode 211 to replace the failed light emitting device.

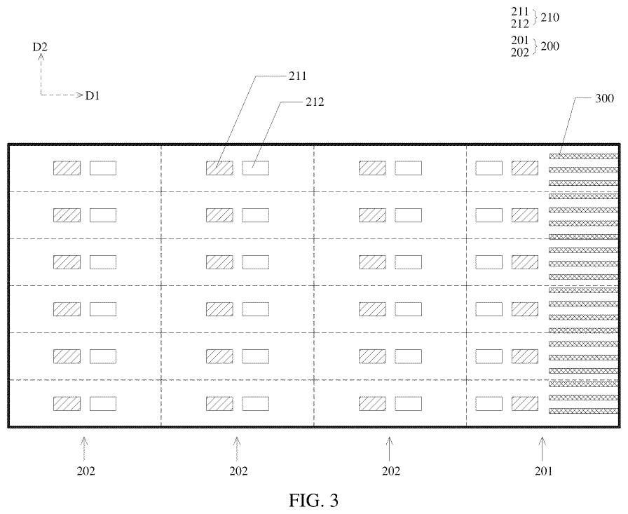

Referring to FIG. 3, which is a top view of a driver backplane provided in present embodiments, a plurality of the bonding electrode sets 210 (as shown by the dashed box in FIG. 3) may form as a plurality of bonding electrode columns 200 extending along a second direction D2 intersecting with the first direction D1 and arrayed along the first direction D1.

Furthermore, in the plurality of bonding electrode columns 200, the bonding electrode column 200 closest to the first side 11 serves as a first bonding electrode column 201, and the bonding electrode columns 200, other than the first bonding electrode column 201 serve as second bonding electrode columns 202.

In the first bonding electrode columns 201, at least part of the backup bonding electrodes 212 of the bonding electrode sets 210 are located on the side of the primary bonding electrode 211 facing away from the first side 11. In the second bonding electrode columns 202, the backup bonding electrodes 212 of the bonding electrode sets 210 are located on the side of the primary bonding electrode 211 adjacent to the first side 11.

That is, the electrode column originally closest to the first side 11 are all the backup bonding electrodes 212. However, in the present embodiments, at least a part of the backup bonding electrodes 212 in the electrode column closest to the first side 11 are repositioned to be located on the side of the primary bonding electrodes 211 corresponding to the backup bonding electrodes 212, where the side of the primary bonding electrodes 211 faces away from the first side 11. Therefore, the space originally occupied by the part of the backup bonding electrodes 212 is used for arranging the side wirings.

Based on the above design, in the present embodiments, by adjusting the positions of the primary bonding electrode 211 and the backup bonding electrode 212 in the first bonding electrode columns 201 adjacent to the first side 11 of the driver backplane, the distance from the bonding electrodes in the first bonding electrode columns 201 that is closest to the first side 11 of the driver backplane can be increased, reserving a larger process space for the side wirings. In this way, when a display panel with a larger pixel density is manufactured, there is a higher fault tolerance rate for the side wirings, thereby improving the yield of the display panels.

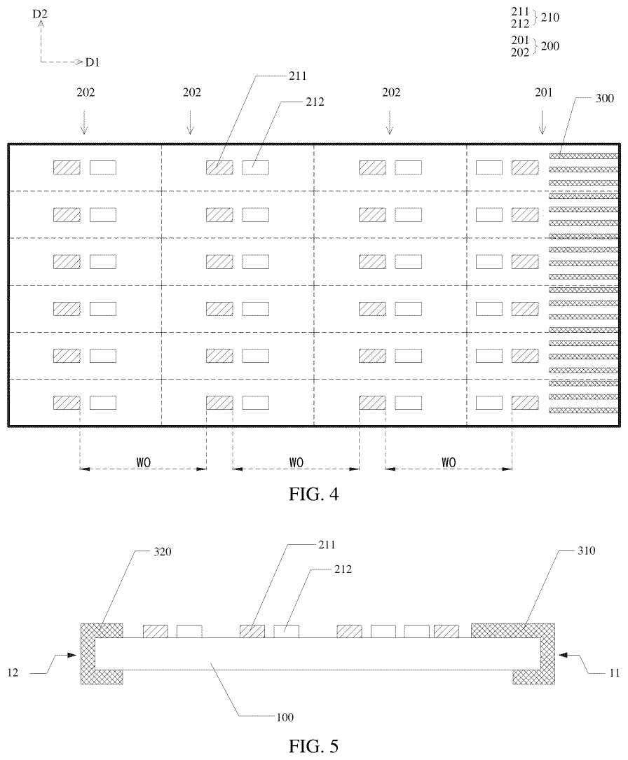

In an embodiment, in the first direction D1, the spacing between the primary bonding electrodes 211 in two adjacent bonding electrode columns 200 is equal. For example, with reference to FIG. 4, in any two adjacent bonding electrode columns 200, a distance between two adjacent primary bonding electrodes 211 in the first direction D1 is W0. In this way, after the light emitting devices are bound to each of the primary bonding electrodes 211, the distances between the light emitting devices bound to the primary bonding electrodes 211 are also equal, thereby ensuring the display uniformity of the display panel and avoiding deformation of the display image.

In an embodiment, still referring to FIGS. 2 and 3, the side wirings of the driver backplane may include a plurality of first side wirings 310 extending from a side of the bonding surface 10 adjacent to the first side surface 11 to the back side of the bonding surface 10 through the first side 11.

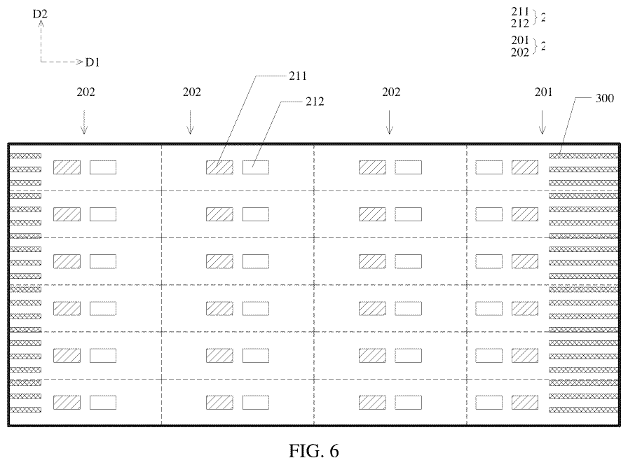

Optionally, referring to FIGS. 5 and 6, the driver backplane further includes a plurality of second side wirings 320 extending from a side of the bonding surface 10 adjacent to the second side 12 to the back side of the bonding surface 10 through the second side 12.

By means of the first side wirings 310 and/or the second side wirings 320, the circuit of the bonding surface 10 of the driver backplane may be connected to the side of the driver backplane facing away from the bonding surface 10 so as to be further connected with a driver chip or other circuit. In this way, the bezel of the driver backplane can be minimized and the display panels using the driver backplane can be seamlessly spliced.

In an embodiment, the backup bonding electrodes 212 of all the bonding electrode sets 210 in the first bonding electrode column 201 are disposed on the side of the primary bonding electrode 211 facing away from the first side 11. For example, still referring to FIG. 3, in all the bonding electrode sets 210 in the first bonding electrode column 201, the backup bonding electrodes 212 are disposed on the side of the primary bonding electrode 211 facing away from the first side 11.

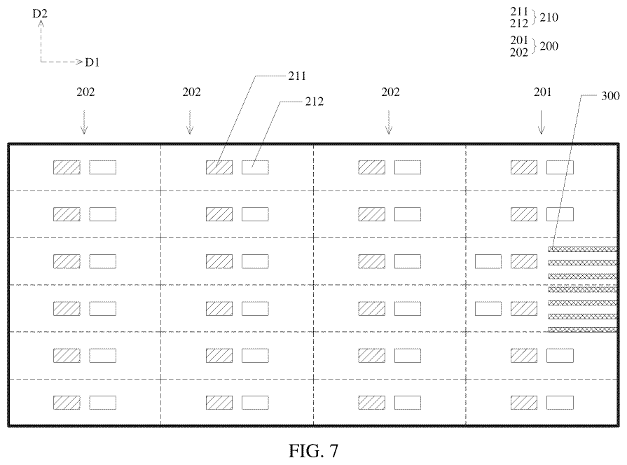

In another embodiment, referring to FIG. 7, in the second direction D2, the backup bonding electrodes 212 in at least a part of adjacent bonding electrode sets 210 in the first bonding electrode column 201 are located on the side of the primary bonding electrodes 211 facing away from the first side 11.

Furthermore, the backup bonding electrode 212 of the bonding electrode sets 210 corresponding to the position of the first side wirings 310 in the first bonding electrode columns 201 are located on the side of the primary bonding electrode 211 facing away from the first side 11.

That is, in the first bonding electrode columns 201, there may be only a part of the bonding electrode sets 210 corresponding to the position of the first side wirings 310, where the backup bonding electrodes 212 are all disposed on the side of the primary bonding electrode 211 facing away from the first side 11.

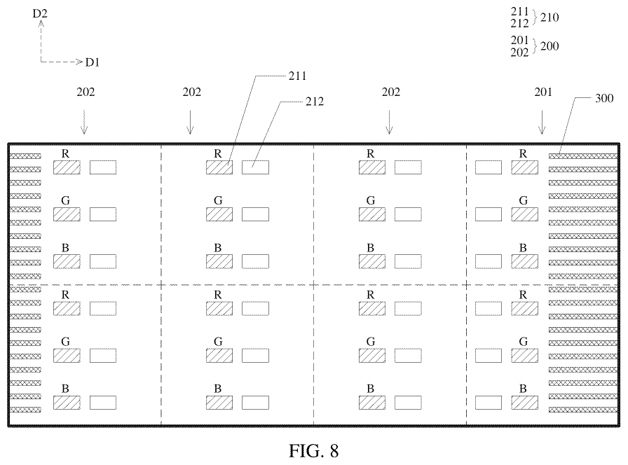

In an embodiment, referring to FIG. 8, in a same bonding electrode column 200, the bonding electrode sets 210 corresponding to the light emitting devices in at least two of different colors are alternately arranged in sequence in the second direction D2. For example, in the embodiments shown in FIG. 8, a dashed box corresponds to a pixel which includes the primary bonding electrode 211 and the backup bonding electrode 212 for bonding the light emitting devices corresponding to the sub-pixels of the colors red R, green G and blue B.

In this way, the bonding electrode sets 210 corresponding to light emitting devices in different colors are arranged alternately in sequence in the second direction D2, and the bonding electrode sets 210 corresponding to light-emitting devices in the same color are adjacent to each other in the first direction D1. In a case where the primary bonding electrodes 211 and the backup bonding electrode 212 have been arranged in the first direction D1, it is possible to avoid that the distance between the primary bonding electrodes 211 corresponding to the light emitting devices in the same color are too far in the first direction D1, and thereby avoiding the striae when a single color is displayed.

Embodiments of the present application further provides a display panel including a driver backplane as described herein and a light emitting device electrically connected to the bonding surface 10 of the driver backplane as provided herein.

The present application further provides a splicing display, the splicing display including at least two of the display panels provided herein, and the first side 11 of the driver backplane of at least one of the display panels is spliced with and attached to the first side 11 or the second side 12 of the driver backplane of the other at least one of the display panels.

In the two display panels spliced in the first direction D1, the first side 11 of one the display panel is spliced with and attached to the second side 12 of the other display panel.

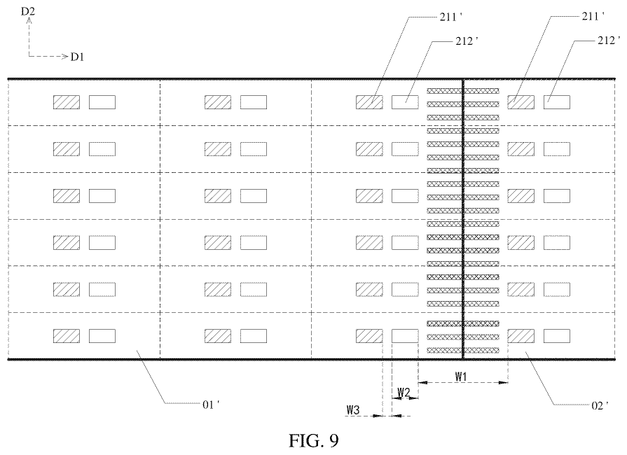

Referring to FIG. 9, FIG. 9 shows a splicing display formed by splicing existing display panels shown in FIG. 1, the splicing display includes a first display panel 01′ and a second display panel 02′, the first side of the first display panel 01′ is spliced with and attached to the second side of the second display panel 02′. In the case where the light emitting devices are all bound to the primary bonding electrodes 211′, the bonding electrode of the first display panel 01′ closest to the second display panel 02′ in the first direction D1 at the splicing position is the backup bonding electrode 212′, the bonding electrode of the second display panel 02′ closest to the first display panel 01′ is the primary bonding electrode 211′. Besides, the minimum spacing between the backup bonding electrode 212′ closest to the second display panel 02 and the primary bonding electrode 211′ of the first display panel 01′ closest to the first display panel 01′ is W1. Furthermore, a width of the light emitting device in the first direction D1 is W2, and a spacing between the primary bonding electrode 211′ and the backup bonding electrode 212′ in the same second bonding electrode column is W3.

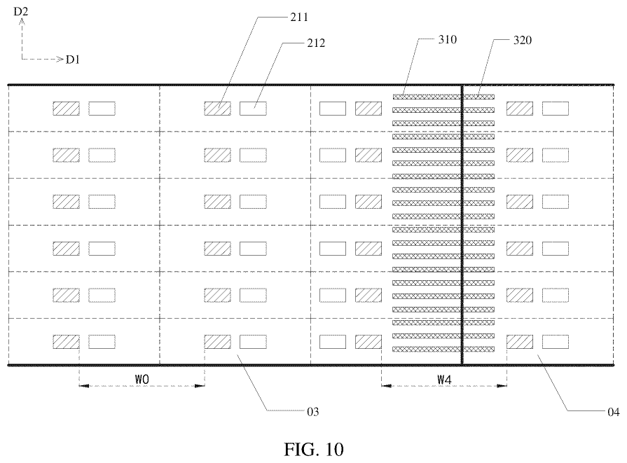

Still referring to FIG. 10, FIG. 10 shows a splicing display formed by splicing of display panels provided by the present embodiments and including a third display panel 03 and a fourth display panel 04. The first side of the third display panel 03 is spliced with and attached to the second side of the fourth display panel 04. In the case where the light emitting devices are all bound to the primary bonding electrodes 211, at the spacing position, in the first direction D1, the bonding electrodes of the third display panel 03 closest to the fourth display panel 04 are the primary bonding electrodes 211, and the bonding electrodes of the fourth display panel 04 closest to the third display panel 03 are also the primary bonding electrodes 211. Furthermore, a minimum spacing between the primary bonding electrodes 211 of the third display panel 03 closest to the fourth display panel 04 and the primary bonding electrodes 211 of the fourth display panel 04 closest to the third display panel 03 is W4, and W4=W1+W2+W3. That is, in the splicing display screen formed by splicing the display panels provided in the present embodiments, a larger process space is reserved for the side wirings at the spacing position.

In an embodiment, still referring to FIG. 10, in the first direction D1, in two adjacent spliced display panels, a distance between the two adjacent primary bonding electrodes 211 at the splicing position is W4, a distance between the primary bonding electrodes 211 of the adjacent second bonding electrode columns in the same display panel is W0, and W4=W0.

In this way, in the case that the light emitting devices are all bound to the primary bonding electrode 211, it can be ensured that the spacing between the light emitting devices at the splicing position is equal to the spacing between the light emitting devices at the other positions to ensure the homogeneity of the image display.

Embodiments of the present application further provides an electronic apparatus including the splicing display provided by the embodiments of the present application. The electronic apparatus may include a monitor, a television, a laptop, a cell phone, a smart wearable device, and other devices having a display function.

In summary, according to the driver backplane, the display panel, and the electronic apparatus provided in the embodiments in the present application, by adjusting the positions of the primary bonding electrodes and the backup bonding electrodes in the first bonding electrode column closest to the first side of the driving backplane, the distance from the bonding electrode in the first bonding electrode column closest to the first side of the driver backboard to the first side of the driver backplane can be increased, and a larger process space is reserved for side wirings, so that the yield of the display panel can be improved when the display panel with larger pixel density is manufactured.

The various technical features of the above-described embodiments may be combined arbitrarily, and all possible combinations of the various technical features of the above-described embodiments have not been described for the sake of conciseness of description; however, as long as there is no contradiction in the combinations of these technical features, they should be considered to be within the scope of the present specification as recorded herein.

What is claimed is:

1. A driver backplane comprising:
a drive function layer comprising a bonding surface, a first side, and a second side, the first side and the second side being disposed on two sides of the bonding surface, respectively, and the first side being configured to attach to and splice with other display panels; and
a plurality of bonding electrode sets disposed on the bonding surface, each of the plurality of bonding electrode sets comprising a plurality of primary bonding electrodes and a plurality of backup bonding electrodes arranged in a first direction,
wherein the plurality of bonding electrode sets are formed as a plurality of bonding electrode columns extending in a second direction and distributing in the first direction that intersects the second direction; and
one of the plurality of the bonding electrode columns closest to the first side serves as a first bonding electrode column, and in the first bonding electrode column, the backup bonding electrodes of at least a part of the bonding electrode sets are disposed on a side of the primary bonding electrodes facing away from the first side; other bonding electrode columns other than the first bonding electrode column serves as second bonding electrode columns, and in the second bonding electrode column, the backup bonding electrodes of the bonding electrode sets are disposed on the other side of the primary bonding electrodes adjacent to the first side.

2. The driver backplane according to claim 1, wherein a distance between the primary bonding electrodes in two adjacent ones of the bonding electrode columns are the same in the first direction.

3. The driver backplane according to claim 1, further comprising: a plurality of first side wirings extending from a side of the bonding surface adjacent to the first side to a back side of the bonding surface though the first side.

4. The driver backplane according to claim 3, further comprising: a plurality of second side wirings extending from the other side of the bonding surface adjacent to the second side to the back side of the bonding surface though the second side.

5. The driver backplane according to claim 4, wherein the backup bonding electrodes in all the bonding electrode sets in the first bonding electrode column are disposed on the side of the primary bonding electrodes facing away from the first side.

6. The driver backplane according to claim 4, wherein in the second direction, the backup bonding electrodes of at least a part of adjacent bonding electrode sets in the first bonding electrode column are disposed on the side of the primary bonding electrodes facing away from the first side.

7. The driver backplane according to claim 4, wherein the backup bonding electrodes of the bonding electrode sets corresponding to a position of the first side wirings in the first bonding electrode column are disposed on the side of the primary bonding electrodes facing away from the first side.

8. The driver backplane according to claim 1, wherein the bonding electrode sets corresponding to the light emitting devices in at least two of different colors in the same bonding electrode column are alternately arranged in sequence in the second direction.

9. A display panel, comprising a light emitting device, and a driver backplane which comprises:
a drive function layer comprising a bonding surface electronically connected to the light emitting device, a first side, and a second side, the first side and the second side being disposed on two sides of the bonding surface, respectively, and the first side being configured to attach to and splice with other display panels; and
a plurality of bonding electrode sets disposed on the bonding surface, each of the plurality of bonding electrode sets comprising a plurality of primary bonding electrodes and a plurality of backup bonding electrodes arranged in a first direction,
wherein the plurality of bonding electrode sets are formed as a plurality of bonding electrode columns extending in a second direction and distributing in the first direction that intersects the second direction;
wherein one of the plurality of the bonding electrode columns closest to the first side serves as a first bonding electrode column, and in the first bonding electrode column, the backup bonding electrodes of at least a part of the bonding electrode sets are disposed on a side of the primary bonding electrodes facing away from the first side; other bonding electrode columns other than the first bonding electrode column serves as second bonding electrode columns, and in the second bonding electrode columns, the backup bonding electrodes of the bonding electrode sets are disposed on the other side of the primary bonding electrodes adjacent to the first side.

10. The display panel according to claim 9, wherein a distance between the primary bonding electrodes in two adjacent ones of the bonding electrode columns are the same in the first direction.

11. The display panel according to claim 9, further comprising: a plurality of first side wirings extending from a side of the bonding surface adjacent to the first side to a back side of the bonding surface though the first side.

12. The display panel according to claim 11, further comprising: a plurality of second side wirings extending from the other side of the bonding surface adjacent to the second side to the back side of the bonding surface though the second side.

13. The display panel according to claim 12, wherein the backup bonding electrodes in all the bonding electrode sets in the first bonding electrode column are disposed on the side of the primary bonding electrodes facing away from the first side.

14. The display panel according to claim 12, wherein in the second direction, the backup bonding electrodes of at least a part of adjacent bonding electrode sets in the first bonding electrode column are disposed on the side of the primary bonding electrodes facing away from the first side.

15. The display panel according to claim 12, wherein the backup bonding electrodes of the bonding electrode sets corresponding to a position of the first side wirings in the first bonding electrode column are disposed on the side of the primary bonding electrodes facing away from the first side.

16. The display panel according to claim 9, wherein the bonding electrode sets corresponding to the light emitting devices in at least two of different colors in the same bonding electrode column are alternately arranged in sequence in the second direction.

17. A splicing display, comprising at least two display panels which comprises a driver backplane, the driver backplane comprising:
a drive function layer comprising a bonding surface electronically connected to the light emitting device, a first side, and a second side, the first side and the second side being disposed on two sides of the bonding surface, respectively, and the first side being configured to attach to and splice with other display panels; and
a plurality of bonding electrode sets disposed on the bonding surface, each of the plurality of bonding electrode sets comprising a plurality of primary bonding electrodes and a plurality of backup bonding electrodes arranged in a first direction,
wherein the plurality of bonding electrode sets are formed as a plurality of bonding electrode columns extending in a second direction and distributing in the first direction, and the second direction that intersects the second direction;
wherein one of the plurality of the bonding electrode columns closest to the first side serves as a first bonding electrode column, and in the first bonding electrode column, the backup bonding electrodes of at least a part of the bonding electrode sets are disposed on a side of the primary bonding electrodes facing away from the first side; other bonding electrode columns other than the first bonding electrode column serves as second bonding electrode columns, and in the second bonding electrode column, the backup bonding electrodes of the bonding electrode sets are disposed on the other side of the primary bonding electrodes adjacent to the first side;
wherein the first side of the driver backplane of at least one of the display panels is spliced with and attached to the first side or the second side of the driver backplane of the other at least one of the display panels.

18. The splicing display according to claim 17, wherein in two adjacent ones of display panels spliced, a distance between two adjacent ones of the primary bonding electrodes at a splicing position is equal to a distance between the primary bonding electrodes of the second bonding electrode columns adjacent in a same display panel in the first direction.
